(19) United States
(12) Patent Application Publication
(10) Pub. No.: US 2026/0212094 A1
(43) Pub. Date: Jul. 23, 2026

(54) AUTOMATIC EXTRACTION METHOD, SYSTEM AND DEVICE FOR SIGNAL PATHS AND STORAGE MEDIUM

(71) Applicant: PRIMARIUS TECHNOLOGIES CO., LTD., Shanghai (CN)

(72) Inventors: Zhu PAN, Shanghai (CN); Zhaofeng HE, Shanghai (CN)

(21) Appl. No.: 19/128,420

(22) PCT Filed: Dec. 28, 2022
(86) PCT No.: PCT/CN2022/142567

§ 371 Date: May 8, 2025

(30) Foreign Application Priority Data
Sep. 22, 2022 (CN) 202211158495.1

(51) Int. Cl. G06F 30/30

(52) U.S. Cl. CPC G06F 30/30

(57) ABSTRACT

An automatic extraction method, system and device for signal paths and a storage medium, include selecting a plurality of target nodes in the simulation process of an integrated circuit, performing simulation operation for the target nodes to obtain a corresponding truth table and finally, analyzing the truth table to extract the corresponding signal path according to an analysis result. The corresponding signal path can be automatically extracted for any standard cell, and the function of the standard cell does not require any pre-acquisition steps or pre-setting by a user, with wide application range. In the extraction process of the signal path corresponding to the standard cell, the truth table is directly analyzed for obtainment, without any user input, and the operation has autonomy and convenience, and has popularization value.

### TECHNICAL FIELD

The present invention relates to the technical field of electronic circuits, and particularly discloses an automatic extraction method, system and device for signal paths and a storage medium.

### BACKGROUND ART

A standard cell must be characterized in order to be understood and used by various tools in the CAD process. For example, a schematic and a layout of the cell are designed. Although the CAD tool can understand the transistor netlist and the layout of the cell, the CAD tool cannot understand them in a way that synthesizes the behavior description into the cell. Other features of the cell, such as input load, speed, and power consumption, also do not have a way that the tool can understand. The synthesis tool needs to know the logical function of the cell, the load of the cell input on a signal connected thereto, the speed of the cell at different input slopes and output loads, the power consumption of the cell, and the area of the cell in order to well synthesize a behavior level description into a set of a series of standard cells. Cell characterization is a process in which a standard cell is simulated by an analog simulator to extract these information that can be understood by other tools, and the extraction of signal paths is the basis of cell characterization: the correctness and completeness of the signal path extraction determine the correctness of the characterization.

In the prior art, in the process of extracting the signal paths or generating the signal paths, the function of the standard cell must be identified at first, or generated based on the custom of a user. If the functional definition of the standard cell cannot be identified, the corresponding signal path cannot be obtained. Generally, in the process of identifying the standard cell, a group of known function groups can be matched to perform identification operation, such as a D-latch, a D-flip-flop, etc.

### SUMMARY OF THE INVENTION

The present invention provides an automatic extraction method, system and device for signal paths and a computer-readable storage medium.

In a first aspect of the present application, an automatic extraction method for signal paths is provided, which may specifically include the following steps:
selecting a plurality of target nodes in the simulation process of an integrated circuit;
performing simulation operation for the target nodes to obtain a corresponding truth table; and
analyzing the truth table to extract the signal path according to an analysis result;
wherein the signal path is used for obtaining cell characterization corresponding to a standard cell in the simulation process of the integrated circuit.

In a possible implementation of the above first aspect, selecting a plurality of target nodes in the simulation process of an integrated circuit includes the following steps:
selecting the target nodes according to a user instruction; and/or
automatically extracting integrated circuit nodes to be excited and/or to be observed as the target nodes in the simulation process of the integrated circuit.

In a possible implementation of the above first aspect, automatically extracting integrated circuit nodes to be excited and/or to be observed as the target nodes includes the following steps:
distinguishing input pins and output pins of a semiconductor device according to the conduction characteristics and the connection relationship of the semiconductor device in the integrated circuit to obtain the distribution condition of the input pins and the output pins;
decomposing according to the distribution condition of the input pins and the output pins and a channel communication relationship of the integrated circuit to obtain a plurality of channel communication blocks; and
analyzing the connection relationship between the channel communication blocks to obtain internal state storage nodes and taking the nodes as the target nodes.

In a possible implementation of the above first aspect, the truth table covers all Boolean combinations of all the input pins and/or the output pins with the corresponding internal state storage nodes;
the Boolean combination that corresponds to each internal state storage node corresponds to a row

In a possible implementation of the above first aspect, performing simulation operation for the target nodes to obtain a corresponding truth table includes:
performing the simulation operation through a simulation circuit simulator; or
performing the simulation operation by a switch-level emulator.

In a possible implementation of the above first aspect, analyzing the truth table to extract the signal path according to an analysis result includes the following steps:
traversing the truth table to combine associated rows according to the changes in an input state; and
judging whether the state change of the associated row combinations conforms to preset electrical characteristics and logic features, and extracting the signal path from the associated row combination that conforms to the preset electrical characteristics and the preset logic features.

In a second aspect of the present application, an automatic extraction system for signal paths is provided, which is applied to the automatic extraction method for signal paths in the above first aspect.

The automatic extraction system for signal paths includes:
a selection cell for selecting a plurality of target nodes in the simulation process of an integrated circuit;
a simulation cell for performing simulation operation for the target nodes to obtain a corresponding truth table; and
an analysis cell for analyzing the truth table to extract the signal path according to an analysis result;
wherein the signal path is used for obtaining cell characterization corresponding to a standard cell in the simulation process of the integrated circuit.

In a possible implementation of the above second aspect, the automatic extraction system for signal paths further includes:
an identification cell for identifying the cell characterization corresponding to the standard cell according to at least one set of matched known functional groups.

In a third aspect of the present application, an automatic extraction device for signal paths is provided, including:
a memory for storing computer programs; and
a processor for implementing the automatic extraction method for signal paths provided in the above first aspect when executing the computer programs.

In a fourth aspect of the present application, a computer-readable storage medium is provided, which stores computer programs, and when executed by a processor, the computer programs implement the automatic extraction method for signal paths provided in the above first aspect.

Compared with the prior art, the present application has the following beneficial effects:
Through the technical solution proposed in the present application, the internal state storage nodes in the integrated circuit can be obtained as the target nodes of simulation based on the direction identification of the input pins and/or the output pins of the standard cell in the channel communication blocks, and then the corresponding signal path can be obtained by extracting the truth table of the target nodes. Through the technical solution provided in the present application, the corresponding signal path can be automatically extracted for any standard cell, and the function of the standard cell does not require any pre-acquisition steps or pre-setting by the user, with wide application range. In the extraction process of the signal path corresponding to the standard cell, the truth table is directly analyzed for obtainment, without any user input, and the operation has autonomy and convenience, and has popularization value.

### BRIEF DESCRIPTION OF THE DRAWINGS

By reading the detailed description of the non-limiting embodiments with reference to the following drawings, other features, purposes and advantages of the present invention will become more apparent.

FIG. 1 shows a flow chart of an automatic extraction method for signal paths according to embodiments of the present application;

FIG. 2 shows a flow chart of automatically extracting integrated circuit nodes to be excited and/or to be observed as target nodes according to embodiments of the present application;

FIG. 3 shows a flow chart of analyzing a truth table to extract a signal path according to an analysis result according to embodiments of the present application;

FIG. 4 shows a structural schematic diagram of an automatic extraction system for signal paths according to embodiments of the present application;

FIG. 5 shows a structural schematic diagram of an automatic extraction device for signal paths according to embodiments of the present application; and

FIG. 6 shows a structural schematic diagram of a computer-readable storage medium according to embodiments of the present application.

### DETAILED DESCRIPTION OF THE INVENTION

The present invention is described in detail below in combination with specific embodiments. The following embodiments will assist those skilled in the art to further understand the present invention, but are not intended to limit the present invention in any way. It should be noted that, for those ordinary skilled in the art, several changes and improvements can also be made without departing from the concept of the present invention. These all belong to the protection scope of the present invention.

The terms “include” and its variations used herein indicate open inclusion, i.e., “include but not limited to”. Unless specifically stated, the term “or” indicates “and/or”. The term “based on” indicates “at least regionally based on”. The terms “one exemplary embodiment” and “one embodiment” indicate “at least one exemplary embodiment”. The term “another embodiment” indicates “at least one other embodiment”. The terms “first”, “second”, etc., can refer to different or identical objects. Other explicit and implied definitions may also be included below.

It can be known based on the relevant description in the above prior art that in the process of extracting the signal path or generating the signal path, the function of the standard cell must be identified at first, or generated based on the custom of the user. However, for the case that the function is unknown or the user does not set in advance, the obtainment of the required signal path cannot be realized. For the above problems, the present application provides an automatic extraction method, system and device for signal paths and a storage medium, wherein a plurality of target nodes are selected in the simulation process of the integrated circuit, and simulation operation is performed for the target nodes to obtain the corresponding truth table. Finally, the truth table is analyzed to extract the corresponding signal path according to the analysis result. There is no need to obtain the function of the standard cell in advance or require the user to customize. The signal path can be extracted for any standard cell. The present application has wide application range, saves related labor cost, and has the popularization value. The technical solutions provided in the present application will be illustrated and explained below in combination with embodiments.

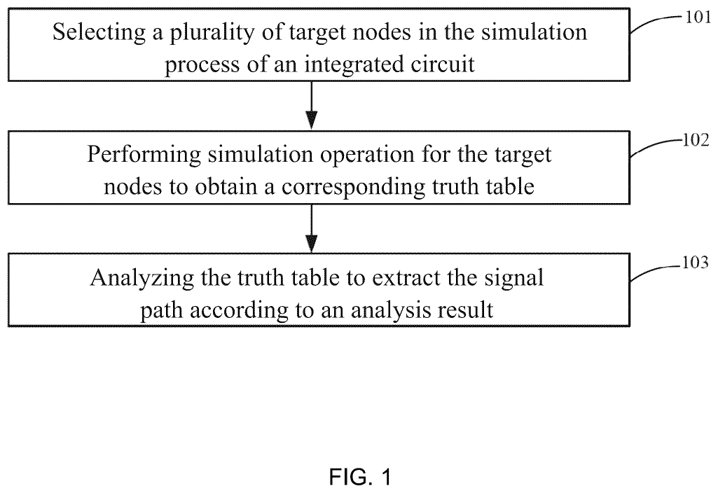

In some embodiments of the present application, FIG. 1 shows a flow chart of an automatic extraction method for signal paths. As shown in FIG. 1, the automatic extraction method for signal paths can specifically include:
Step 101: selecting a plurality of target nodes in the simulation process of an integrated circuit, wherein the specific selection process of the target nodes will be illustrated and explained in detail in the following article.
Step 102: performing simulation operation for the target nodes to obtain a corresponding truth table.
Step 103: analyzing the truth table to extract the signal path according to an analysis result, wherein the signal path is used for obtaining cell characterization corresponding to a standard cell in the simulation process of the integrated circuit. The specific analysis process of the truth table will be explained in the following article.

Through the above step 101 to step 103, the obtainment of the signal path for any standard cell can be realized, and then the obtainment of the cell characterization for the standard cell is facilitated, without intervention of manual operation, with wide applicability. The specific implementation process of the above step 101 to step 103 will be described below.

In some embodiments of the present application, further, in the selection process of the target nodes, the selection behavior may be the target node selection conducted according to the custom condition of the user, or the automatic selection of the integrated circuit nodes to be excited and/or to be observed in the simulation process of the integrated circuit, which will not be limited herein. It can be understood that in the process of automatic extraction of the signal path, the user is allowed to customize and select part of target nodes in the integrated circuit, and the remaining target nodes are conducted by the system autonomously through the implementation of an automatic selection method, thereby ensuring the efficiency and the accuracy of automatic extraction of the signal path and saving the corresponding manual intervention cost.

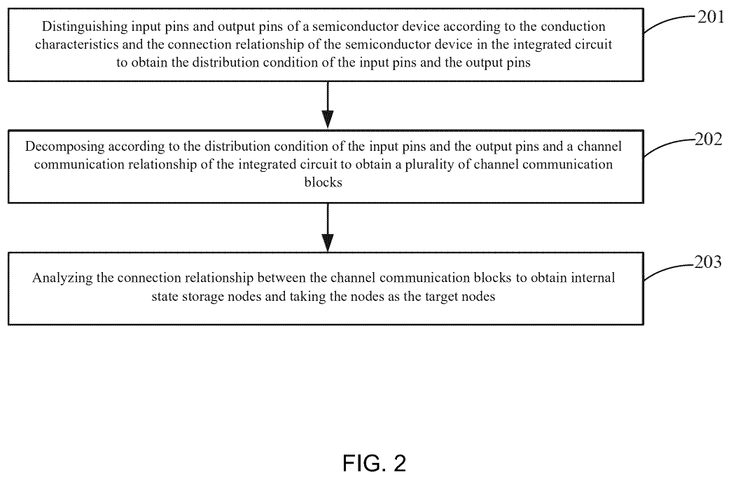

Further, FIG. 2 shows a flow chart of automatically extracting integrated circuit nodes to be excited and/or to be observed as target nodes. Specifically, as shown in FIG. 2, the following steps can be included:
Step 201: distinguishing input pins and output pins of a semiconductor device according to the conduction characteristics and the connection relationship of the semiconductor device in the integrated circuit to obtain the distribution condition of the input pins and the output pins.
Step 202: decomposing according to the distribution condition of the input pins and the output pins and a channel communication relationship of the integrated circuit to obtain a plurality of channel communication blocks.
Step 203: analyzing the connection relationship between the channel communication blocks to obtain internal state storage nodes and taking the nodes as the target nodes.

It can be understood that in the execution process of the above step 201 to step 203, the input pins and the output pins can be distinguished according to the conduction characteristics and the connection relationship of the semiconductor device in the integrated circuit, and the internal state storage nodes are found. For example, the above conduction characteristics can include a conduction relationship between a gate control source and a drain. In general, the input pins are connected with a signal source, and the output pins are connected with a source or the drain. Then, decomposition can be conducted from the output pins according to the channel communication relationship to form channel communication blocks (CCB). The internal state storage nodes and the voltage of each pin and node can be obtained by analyzing the connection relationship of the channel communication blocks. The above channel communication block (CCB) refers to a channel connection part from the source to the drain of the cell. For example, a single-level cell (such as inverter, NAND gate and NOR gate cells) only includes one channel communication block, that is, the entire cell is connected through only one channel connection region, while a multilevel cell (such as AND gate and OR gate cells) includes a plurality of channel communication blocks. The distribution condition of the internal state storage nodes and the corresponding voltage condition can be intuitively obtained through the connection relationship of the channel communication blocks.

In some embodiments of the present application, in the process of performing simulation operation for the target nodes, the above simulation operation can include conducting the simulation operation through a simulation circuit simulator (SPICE), or conducting the simulation operation through a switch-level simulator, which will not be limited herein. Those skilled in the art can select an appropriate simulation operation mode according to practical application conditions.

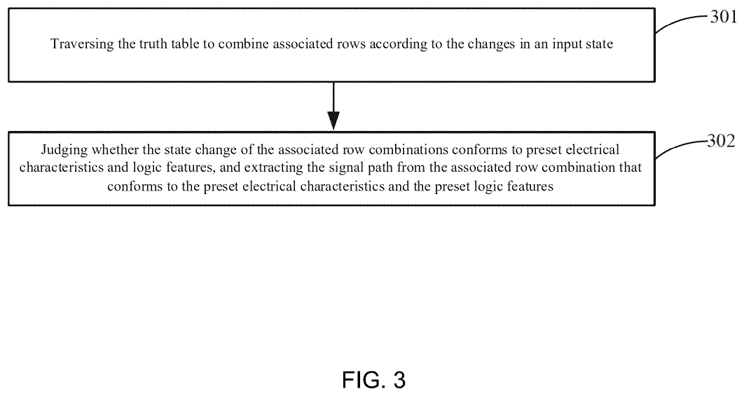

In some embodiments of the present application, FIG. 3 shows a flow chart of analyzing a truth table to extract a signal path according to an analysis result. Specifically, as shown in FIG. 3, the following steps can be included:
Step 301: traversing the truth table to combine associated rows according to the changes in an input state.
Step 302: judging whether the state change of the associated row combinations conforms to preset electrical characteristics and logic features, and extracting the signal path from the associated row combination that conforms to the preset electrical characteristics and the preset logic features.

It can be understood that, based on the automatic extraction solution for the target nodes provided by the above embodiments, the truth table covers all Boolean combinations of all the input pins and/or the output pins with the corresponding internal state storage nodes. If there are N internal state storage nodes, there are corresponding 2^{N} Boolean combinations. The Boolean combination that corresponds to each internal state storage node corresponds to a row in the truth table. By traversing the truth table, under the condition that the input state of the integrated circuit is changed, rows that have associated changes are known and these associated row combinations can be known and extracted through the truth table.

Further, after the associated row combinations are obtained, it is also necessary to observe whether the state changes of the associated rows are consistent with the electrical characteristics and the logical features corresponding to the integrated circuit. The relevant electrical characteristics and logical features can be obtained through analog simulation of the integrated circuit, which is not limited herein. Those skilled in the art can select an appropriate verification procedure according to practical application conditions. Under the condition that the obtained associated row combinations conform to the relevant electrical characteristics and logical features, the corresponding signal path can be obtained according to the node distribution condition corresponding to the associated row combinations.

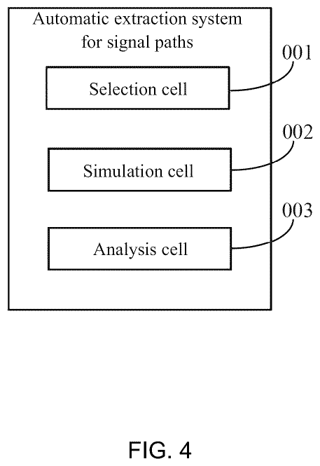

In some embodiments of the present application, FIG. 4 provides an automatic extraction system for signal paths, which is applied to the automatic extraction method for signal paths provided in the above embodiments. Specifically, as shown in FIG. 4, the automatic extraction system for signal paths can include:
A selection cell 001 for selecting a plurality of target nodes in the simulation process of an integrated circuit.
A simulation cell 002 for performing simulation operation for the target nodes to obtain a corresponding truth table.
An analysis cell 003 for analyzing the truth table to extract the signal path according to an analysis result, wherein the signal path is used for obtaining cell characterization corresponding to a standard cell in the simulation process of the integrated circuit.

It can be understood that the functions realized by the selection cell 001 to the analysis cell 003 in the above functional modules correspond to the actions performed by step 101 to step 103 in the above embodiments, and are not repeated here.

Further, in the solution provided by the above embodiments, the automatic extraction system for signal paths may also include an identification cell for identifying the cell characterization corresponding to the standard cell according to at least one set of matched known functional groups. It can be understood that the above prior art has proposed that a group of known function groups (such as a D-latch, a D-flip-flop, etc.) can be matched to perform the identification operation for the standard cell. The automatic extraction system for signal paths provided in the above embodiments is also compatible with the above functional modules for identifying the functions of the standard cell.

In some embodiments of the present application, an automatic extraction device for signal paths is also provided, which can include:
a memory for storing computer programs; and
a processor for implementing the steps of the automatic extraction method for signal paths described in the technical solution of the present application when executing the computer programs.

It can be understood that various aspects of the technical solution of the present application may be implemented as a system, method or program product. Therefore, various aspects of the technical solution of the present application may be concretely implemented in the following form, i.e., a full hardware implementation mode, a full software implementation mode (including firmware, microcode, etc.), or an implementation mode of a combination of hardware and software aspects, which may be collectively referred to as a “circuit”, a “module” or a “platform”.

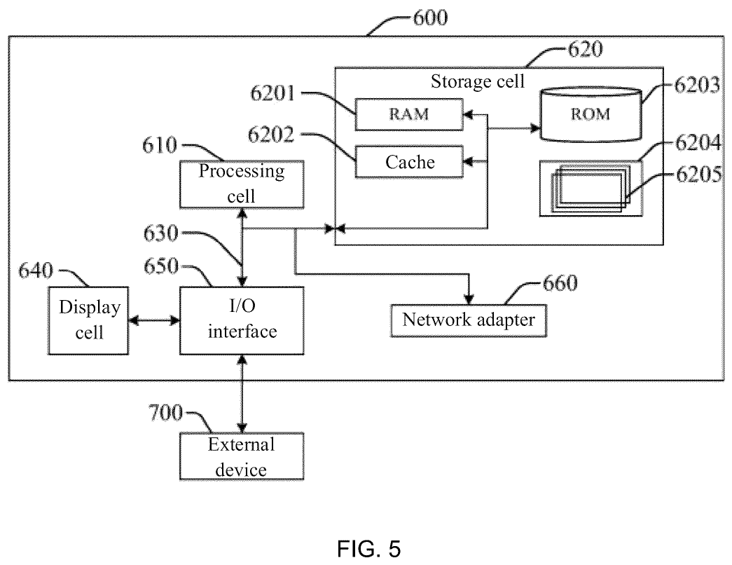

FIG. 5 shows a structural schematic diagram of an automatic extraction device for signal paths according to some embodiments of the present application. An electronic device 600 implemented according to the implementation mode in the present embodiment is described in detail below with reference to FIG. 5. The electronic device 600 shown in FIG. 5 is only an example and should not impose any limitation on the function and the use scope of any embodiment of the technical solution of the present application.

As shown in FIG. 5, the electronic device 600 is represented as a general-purpose computing device. The construction of the electronic device 600 can include, but is not limited to, at least one processing cell 610, at least one storage cell 620, a bus 630 connecting different platform assemblies (including the storage cell 620 and the processing cell 610), a display cell 640, etc.

Wherein the storage cell stores program codes, and the program codes can be executed by the processing cell 610, so that the processing cell 610 executes the specific implementation steps of the automatic extraction method for signals path in the present embodiment. For example, the processing cell 610 can execute the steps shown in FIG. 1 to FIG. 3.

The storage cell 620 can include a readable medium in the form of a volatile storage cell, such as a random access memory (RAM) 6201 and/or a cache storage cell 6202, and may further include a read-only memory (ROM) 6203.

The storage cell 620 can also include programs/utilities 6204 having a set (at least one) of program modules 6205. Such program modules 6205 include, but not limited to, an operating system, one or more application programs, other program modules, and program data, and each or a certain combination of these examples may include the implementation of a network environment. The bus 630 may represent one or more of several classes of bus structures, including a storage cell bus or a storage cell controller, a peripheral bus, an image acceleration port, a processing cell, or a local bus using any bus structure in several bus structures.

The electronic device 600 can also communicate with one or more external devices 700 (such as keyboards, pointing devices, Bluetooth devices, etc.), and can also communicate with one or more devices that enable the user to interact with the electronic device 600, and/or communicate with any device (such as a router, a modem, etc.) that enables the electronic device to communicate with one or more other computing devices. This communication can be conducted through an input/output (I/O) interface 650. In addition, the electronic device 600 can also communicate with one or more networks (such as a local area network (LAN), a wide area network (WAN) and/or a public network, e.g. Internet) through a network adapter 660. The network adapter 660 can communicate with other modules of the electronic device 600 through the bus 630. It should be understood that, although not shown in FIG. 5, other hardware and/or software modules may be used in conjunction with the electronic device 600, including but not limited to: microcode, device drivers, redundant processing cells, external disk drive arrays, RAID systems, tape drivers, data backup storage platforms, etc. In some embodiments of the present application, a computer-readable storage medium is further provided, which stores computer programs, and when executed by a processor, the computer programs can implement the relevant steps of the automatic extraction method for signal paths provided in the above embodiments.

Although other specific implementation modes are not enumerated in detail in the present embodiment, in some possible implementation modes, various aspects described in the technical solution of the present application can also be implemented in the form of a program product, including program codes. When a program product is run on a terminal device, the program codes are used to enable the terminal device to perform the steps described in an image stitching method region of the technical solution of the present application according to the implementation modes in various embodiments of the technical solution of the present application.

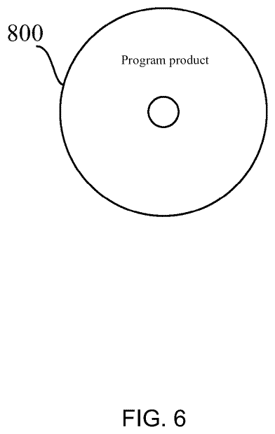

FIG. 6 shows a structural schematic diagram of a computer-readable storage medium according to some embodiments of the present application. As shown in FIG. 6, a program product 800 for implementing the above method according to the implementation modes of the technical solution of the present application is described, which may adopt a portable compact disk read-only memory (CD-ROM), includes the program codes, and may be run on a terminal device, such as a personal computer. Of course, the program product generated according to the present embodiment is not limited to this. In the technical solution of the present application, the readable storage medium may be any tangible medium including or storing a program. The program may be used by or used in combination with an instruction execution system, apparatus or device.

The program product can adopt any combination of one or more readable media. The readable media can be readable signal media or readable storage media. The readable storage media, for example, can be, but not limited to, electrical, magnetic, optical, electromagnetic, infrared, or semiconductor systems, apparatuses or devices, or any combination of the above. More specific examples (a non-exhaustive list) of the readable storage media include: electrical connection having one or more wires, portable disks, hard disks, random access memory (RAM), read-only memory (ROM), erasable programmable read-only memory (EPROM or flash memory), optical fibers, portable compact disk read-only memory (CD-ROM), optical memory device, magnetic memory device, or any suitable combination of the above.

The computer-readable storage medium can include a data signal propagated in a baseband or as a carrier in a region, which carries readable program codes. This propagated data signal can adopt many forms, including but not limited to electromagnetic signals, optical signals, or any suitable combination of the above. The readable storage medium can also be any readable medium other than the readable storage medium. The readable medium can send, propagate or transmit a program used by or used in combination with an instruction execution system, apparatus or device. The program codes included on the readable storage medium can be transmitted with any appropriate medium, including but not limited to wireless, wired, optical cable, RF, etc., or any suitable combination of the above. The program codes used for performing the operation of the technical solution of the present application can be written in any combination of one or more programming languages. The programming languages include object-oriented programming languages-such as Java, C++, etc., and also include conventional procedural programming languages-such as C language or similar programming languages. The program codes can be executed completely on a user computing device, executed regionally on user equipment, executed as a stand-alone software package, executed regionally on the user computing device and executed regionally on a remote computing device, or executed completely on the remote computing device or a server. In the case of the remote computing device, the remote computing device can be connected to the user computing device through any kind of network, including a local area network or a wide area network, or can be connected to an external computing device (e.g., connected by using an Internet service provider through Internet).

In conclusion, through the technical solution provided in the present application, the corresponding signal path can be automatically extracted for any standard cell, and the function of the standard cell does not require any pre-acquisition steps or pre-setting by the user, with wide application range. In the extraction process of the signal path corresponding to the standard cell, the truth table is directly analyzed for obtainment, without any user input, and the operation has autonomy and convenience, and has popularization value.

The above description is only the description of preferred embodiments of the technical solution of the present application, and is not any limitation on the scope of the technical solution of the present application. Any changes and modifications made by those ordinary skilled in the art of the technical solution of the present application according to the above disclosed content belong to the protection scope of the claims.

1. An automatic extraction method for signal paths, wherein the automatic extraction method comprises the following steps:
selecting a plurality of target nodes in the simulation process of an integrated circuit;
performing simulation operation for the target nodes to obtain a corresponding truth table; and
analyzing the truth table to extract the signal path according to an analysis result;
wherein the signal path is used for obtaining cell characterization corresponding to a standard cell in the simulation process of the integrated circuit.

2. The automatic extraction method for signal paths according to claim 1, wherein the selecting a plurality of target nodes in the simulation process of an integrated circuit comprises the following steps:
selecting the target nodes according to a user instruction; and/or automatically extracting integrated circuit nodes to be excited and/or to be observed as the target nodes in the simulation process of the integrated circuit.

3. The automatic extraction method for signal paths according to claim 2, wherein the automatically extracting integrated circuit nodes to be excited and/or to be observed as the target nodes comprises the following steps:
distinguishing input pins and output pins of a semiconductor device according to the conduction characteristics and the connection relationship of the semiconductor device in the integrated circuit to obtain the distribution condition of the input pins and the output pins;
decomposing according to the distribution condition of the input pins and the output pins and a channel communication relationship of the integrated circuit to obtain a plurality of channel communication blocks; and
analyzing the connection relationship between the channel communication blocks to obtain internal state storage nodes and taking the nodes as the target nodes.

4. The automatic extraction method for signal paths according to claim 3, wherein the truth table covers all Boolean combinations of all the input pins and/or the output pins with the corresponding internal state storage nodes;
the Boolean combination that corresponds to each internal state storage node corresponds to a row in the truth table.

5. The automatic extraction method for signal paths according to claim 1, wherein the performing simulation operation for the target nodes to obtain a corresponding truth table comprises:
performing the simulation operation through a simulation circuit simulator; or performing the simulation operation by a switch-level emulator.

6. The automatic extraction method for signal paths according to claim 1, wherein the analyzing the truth table to extract the signal path according to an analysis result comprises the following steps:
traversing the truth table to combine associated rows according to the changes in an input state; and
judging whether the state change of the associated row combinations conforms to preset electrical characteristics and logic features, and extracting the signal path from the associated row combination that conforms to the preset electrical characteristics and the preset logic features.

7. An automatic extraction system for signal paths, being applied to the automatic extraction method for signal paths according to claim 1;
wherein the automatic extraction system for signal paths comprises:
a selection cell for selecting a plurality of target nodes in the simulation process of an integrated circuit;
a simulation cell for performing simulation operation for the target nodes to obtain a corresponding truth table; and
an analysis cell for analyzing the truth table to extract the signal path according to an analysis result;
wherein the signal path is used for obtaining cell characterization corresponding to a standard cell in the simulation process of the integrated circuit.

8. The automatic extraction system for signal paths according to claim 7, wherein the automatic extraction system for signal paths further comprises:
an identification cell for identifying the cell characterization corresponding to the standard cell according to at least one set of matched known functional groups.

9. (canceled)

10. A computer-readable storage medium, wherein the computer-readable storage medium stores computer programs, and when executed by a processor, the computer programs implement the automatic extraction method for signal paths according to any claim 1.
